(19) United States
(12) Patent Application Publication
(10) Pub. No.: US 2024/0097403 A1
(43) Pub. Date: Mar. 21, 2024

(54) LASER DEVICE

(71) Applicant: UNIKORN SEMICONDUCTOR CORPORATION, Hsinchu (TW)

(72) Inventors: Jung-Jen Li, Hsinchu (TW); Ching-En Huang, Hsinchu (TW); Hao-Ming Ku, Hsinchu (TW); Shih-I Chen, Hsinchu (TW)

(21) Appl. No.: 18/368,057

(22) Filed: Sep. 14, 2023

(30) Foreign Application Priority Data
Sep. 20, 2022 (TW) 111210218

(51) Int. Cl. H01S 5/20; H01S 5/042

(52) U.S. Cl. CPC H01S 5/2027; H01S 5/04254

(57) ABSTRACT

A laser device is provided. The laser device includes a stack of epitaxial layers, a first conductive layer, an intermediate layer, and a first electrode. The stack of epitaxial layers has a central region and an edge region. The stack of epitaxial layers includes a first reflective structure, an active region disposed on the first reflective structure, a second reflective structure disposed on the active region. The first conductive layer disposes on the stack of epitaxial layers and covers the central region and at least a part of the edge region. The intermediate layer has a first opening that corresponding to the central region of the stack of epitaxial layers, wherein the intermediate layer comprises insulating material or metal. The first electrode disposes on the first conductive layer.

### CROSS REFERENCE TO RELATED APPLICATIONS

This application claims priority of Taiwan Patent Application No. 111210218, filed on Sep. 20, 2022, and the entirety of which is incorporated by reference herein.

### BACKGROUND

### Technical Field

The present application relates to a laser device, and, in particular, to a laser device with a conductive layer.

### Description of the Background Art

Laser devices are used in a wide range of applications while the research and development of related materials is ongoing. For example, III-V group semiconductor materials may be applied to various laser devices, and the laser diode may be used in various fields, for example, luminance, medical treatment, display, communication, sensing, and power system. Therefore, with the development of technology, there are still many needs of technology research and development for laser devices. Although existing laser devices have generally been adequate for their intended use, they have not been entirely satisfactory in all respects. Therefore, there are still some issues to be addressed regarding laser devices.

### SUMMARY

Some embodiments of the present disclosure provide a laser device. The laser device includes a stack of epitaxial layers, a first conductive layer, an intermediate layer, and a first electrode. The stack of epitaxial layers has a central region and an edge region. The stack of epitaxial layers includes a first reflective structure, an active region disposed on the first reflective structure, a second reflective structure disposed on the active region. The first conductive layer disposes on the stack of epitaxial layers and covers the central region and at least a part of the edge region. The intermediate layer has a first opening that corresponding to the central region of the stack of epitaxial layers, wherein the intermediate layer comprises insulating material or metal. The first electrode disposes on the first conductive layer.

Some embodiments of the present disclosure provide a laser device. The laser device includes a substrate, a stack of epitaxial layers, a conductive layer, a bonding layer, and a first electrode. The stack of epitaxial layers disposes on the substrate and includes a first reflective structure, a current confinement structure disposed on or within the first reflective structure, an active region disposed on the current confinement structure, and a second reflective structure disposed on the active region. The current confinement structure defines a current conductive region. The conductive layer disposes between the substrate and the stack of epitaxial layers. The bonding layer disposed between the substrate and the conductive layer. The first electrode disposes on the stack of epitaxial layers.

### BRIEF DESCRIPTION OF THE DRAWINGS

The embodiment of the application can be more fully understood by reading the subsequent detailed description and examples with references made to the accompanying drawings. It is noted that, in accordance with the standard practice in the industry, various features are not drawn to scale and are merely used for illustration. In fact, the dimensions of the various components may be arbitrarily increased or reduced to clearly represent the features of the embodiments of the present disclosure. In the accompanying drawings:

FIGS. 1-7 show cross-sectional views of laser devices, in accordance with some embodiments of the present disclosure;

FIG. 8 shows a top view of a laser device having a plurality of the stack of epitaxial layers, in accordance with some embodiments of the present disclosure; and

FIGS. 9-14 show cross-sectional views of laser devices having a plurality of the stack of epitaxial layers, in accordance with some embodiments of the present disclosure.

### DETAILED DESCRIPTION OF THE PREFERRED EMBODIMENTS

The following disclosure provides many different embodiments, or examples, for implementing different components of the provided subject matter. Specific examples of components and arrangements are described below to simplify the present disclosure. These are, of course, merely examples and are not intended to limit the present disclosure. For example, the formation of a first component over or on a second component in the following description may include embodiments in which the first and second components are formed in direct contact, and may also include embodiments in which additional components may be located between the first and second components, such that the first and second components may not be in direct contact. In addition, the present disclosure may repeat reference numerals and/or letters in the various examples. This repetition is for the purpose of simplicity and clarity and does not in itself dictate a relationship between the various embodiments and/or configurations. Besides, various components may be arbitrarily drawn in various scale for the purpose of simplicity and clarity.

Further, spatially relative terms, such as “under,” “below,” “lower,” “above,” “upper” and the like, may be used herein for simply describe one element or feature's relationship to another element(s) or feature(s) as illustrated in the figures. The spatially relative terms are intended to encompass different orientations of the device in use or operation in addition to the orientation depicted in the figures. For example, if a device in the figures were turned over, elements described as being “lower” or “below” other elements or components would then be changed as “above” the other elements or components. Therefore, illustrative term “below” may both have orientations of “above” and “below”. The component may be otherwise oriented (rotated 90 degrees or at other orientations) and the spatially relative descriptors used herein may likewise be interpreted accordingly.

In order to increase the carrier recombination to improve the laser performance of the existing vertical cavity surface emitting laser (VCSEL) diode during operation, a current confinement layer may be disposed in the laser device. Nevertheless, in the conventional laser device, the current may concentrate at the opening edge of the wet oxidation layer with current confining function, thereby decreasing the performance of the laser device. To address the issues, in the laser device provided by embodiments of the present application, a conductive layer may be disposed above and/or below a current confinement layer, and an opening of the upper or lower conductive layer may be located corresponding to the opening of the current confinement layer. Therefore, in the present disclosure, not only the concentrated current at the opening edge of the wet oxidation layer with current confining function may be further reduced, but also current confinement properties may be increased, thereby improving the quality of the laser device.

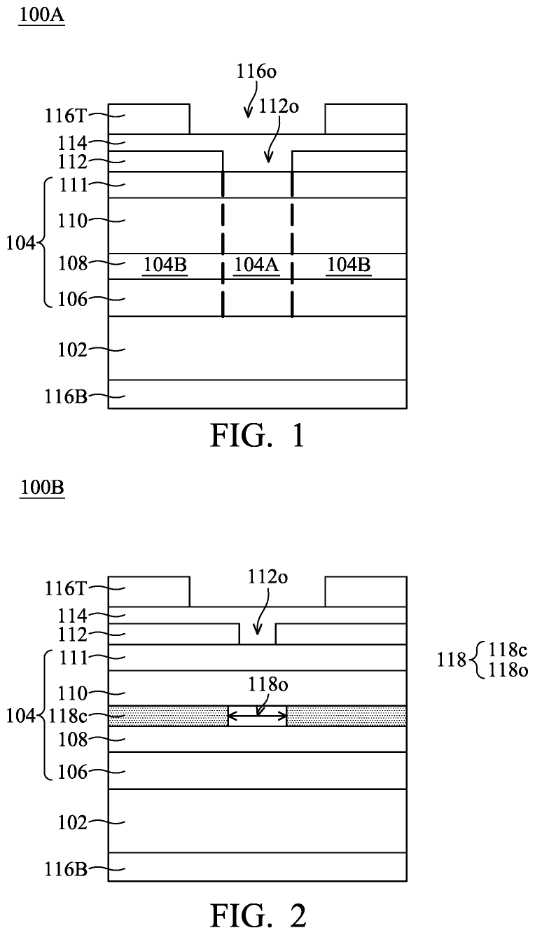

FIG. 1 shows a cross-sectional view of a laser device 100A in accordance with an embodiment of the present disclosure. Referring to FIG. 1, the laser device 100A includes: a substrate 102 and a stack of epitaxial layers 104 formed on the substrate 102. In this embodiment, the substrate 102 is gallium arsenide (GaAs).

The stack of epitaxial layers 104 may be formed of epitaxial stacking of several semiconductor compound layers. In some embodiments, the stack of epitaxial layers 104 sequentially includes, from bottom to top, a first reflective structure 106, an active region 108, and a second reflective structure 110.

The first reflective structure 106 and the second reflective structure 110 include III-V group compound semiconductor materials respectively. In an embodiment, the first reflective structure 106 and the second reflective structure 110 may include a stack of multiple III-V group compound semiconductor materials. In detail, the first reflective structure 106 and the second reflective structure 110 have a stack including multiple pairs of periodically alternating layers with two different refractive indexes. For example, pairs of AlGaAs layer with a high aluminum composition and AlGaAs layer with a low aluminum composition periodically alternating stack to form a distributed Bragg reflector (DBR). Consequently, the light emitted from the active region 108 may be reflected within the first reflective structure 106 and the second reflective structure 110 to form a coherent light. In some embodiments, the number of pairs of periodically alternating layers with two different reflective indexes may be 2 to 100 (such as 20, 40, 60, or 80 pairs). In some embodiments, the reflective index of the first reflective structure 106 is higher than that of the second reflective structure 110, thereby emitting the coherent light toward the direction away from the substrate 102. In some embodiments, the material of the first reflective structure 106 and the second reflective structure 110 may respectively include InGaAs, GaAs, GaP, InP, AlGaInP, AlGaAs, and/or a combination thereof.

An active region 108 for light emission is disposed between the first reflective structure 106 and the second reflective structure 110. In an embodiment, the active region 108 may have a multiple quantum well (MQW) structure formed of semiconductor material. The active region 108 may include suitable luminous materials. For example, different materials may be chosen according to the needs of a laser device. For example, in an embodiment that the laser device emits an infrared light with a wavelength greater than 800 nm (such as 850 nm or 940 nm), the material of the active region 108 may include aluminum (Al), gallium (Ga), arsenic (As), phosphorous (P), indium (In), and/or a combination thereof. The abovementioned embodiments are for illustrative purpose only, and the disclosure is not limited thereto.

In some embodiments, the stack of epitaxial layers 104 including the first reflective structure 106, the active region 108, and the second reflective structure 110 may be formed by epitaxial growth processes, such as metal-organic chemical vapor deposition (MOCVD), hydride vapor phase epitaxy (HYPE), molecular beam epitaxy (MBE), liquid-phase epitaxy (LPE), vapor phase epitaxy (VPE), or a combination thereof. In an embodiment, the first reflective structure 106, the active region 108, and the second reflective structure 110 are formed by the metal-organic chemical vapor deposition (MOCVD).

In some embodiments, the doping of the first reflective structure 106 and the second reflective structure 110 may be performed by in-situ doping during the epitaxial growth, and/or implantation using dopants after the epitaxial growth. The first reflective structure 106 may include a first dopant to have a first conductive type, while the second reflective structure 110 may include a second dopant to have a second conductive type. The first reflective structure 106 and the second reflective structure 110 have different conductive types, that is to say, the first conductive type and the second conductive type are different. For example, the first conductive type is p-type and the second conductive type is n-type to provide electron holes and electrons respectively; or, the first conductive type is n-type and the second conductive type is p-type to provide electrons and electron holes respectively. In an embodiment, the first dopant or the second dopant may be: magnesium (Mg), zinc (Zn), silicon (Si), carbon (C), or tellurium (Te). In an embodiment, the first reflective structure 106 is n-type and the first dopant is silicon, and the second reflective structure 110 is p-type and the second dopant is carbon.

Still referring to FIG. 1, the stack of epitaxial layers 104 may optionally include a contact layer 111 located on the second reflective structure 110. The contact layer 111 may have the same conductive type with the second reflective structure 110 and have a third dopant. The concentration of the third dopant in the contact layer 111 is greater than that of the second dopant in the second reflective structure 110. The third dopant may be silicon (Si) or carbon (C). The third dopant may be the same or different from the second dopant. In an embodiment, the contact layer 111 is GaAs. The contact layer 111 may be formed by a similar process of forming the first reflective structure 106 or the second reflective structure 110, or other suitable processes, which is omitted herein for the sake of brevity.

As shown in FIG. 1, the laser device 100A further includes an intermediate layer 112. The stack of epitaxial layers 104 has an edge region 104B and a central region 104A. The intermediate layer 112 is located on the stack of epitaxial layers 104 and corresponding to the edge region 104B. The intermediate layer 112 has a first opening 112o corresponding to the central region 104A. The intermediate layer 112 may be transparent or opaque to the light emitted from the active region 108. In this embodiment, the intermediate layer 112 may include an insulating material, such as SiO₂, SiNₓ, TiO₂, Ta₂O₅, Al₂O₃, or combinations of multi-layers thereof. The intermediate layer 112 may be formed by chemical vapor deposition (CVD), plasma enhanced chemical vapor deposition (PECVD), atomic layer deposition (ALD), or other suitable deposition processes. In this embodiment, the intermediate layer 112 may act as a current confinement layer to restrict the direction of current, thereby improving the performance of the laser device.

Still referring to FIG. 1, the laser device 100A further includes a first conductive layer 114 disposed on the intermediate layer 112 and the stack of epitaxial layers 104. The first conductive layer 114 fills the first opening 112o and directly contacts the stack of epitaxial layers 104. More specifically, the first conductive layer 114 covers the central region 104A of the stack of epitaxial layers 104, and partially or completely covers the edge region 104B of the stack of epitaxial layers 104. In other words, the first conductive layer 114 covers the central region 104A and at least a part of the edge region 104B of the stack of epitaxial layers 104. In this embodiment, the first conductive layer 114 fills up the first opening 112o. The first conductive layer 114 can reduce the concentrated current at the edge of the first opening 112o, thereby improving the performance of the laser device. The first conductive layer 114 may be transparent and include a metal oxide, for example, indium tin oxide (ITO) or indium zinc oxide (IZO). The first conductive layer 114 may be formed by, for example, chemical vapor deposition (CVD), physical vapor deposition (PVD), evaporation deposition, sputter deposition, or other suitable deposition processes.

As shown in FIG. 1, the laser device 100A further include a first electrode 116T and a second electrode 116B. The first electrode 116T is deposed on the first conductive layer 114, and the first electrode 116T has a second opening 116o to expose a portion of the first conductive layer 114. The second electrode 116B is disposed under the substrate 102. In this embodiment, the second opening 116o corresponds to the first opening 112o. The first opening 112o has a first width, and the second opening 116o has a second width greater than the first width to ensure the light beam generated by the laser device 100A can be emitted through the first opening 112o.

In some embodiments, the material of the first electrode 116T and the second electrode 116B may be the same or different, and may respectively include metal oxide materials, metals or alloys. The metal oxide material may include indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO), or indium zinc oxide (IZO). The metal may include germanium (Ge), beryllium (Be), zinc (Zn), gold (Au), platinum (Pt), titanium (Ti), aluminum (Al), nickel (Ni), or copper (Cu). The alloy may include at least two metals selected from the abovementioned metals, for example, germanium-gold-nickel (GeAuNi), beryllium-gold (BeAu), germanium-gold (GeAu), or zinc-gold (ZnAu). The first electrode 116T and/or the second electrode 116B may be formed by chemical vapor deposition (CVD), physical vapor deposition (PVD), evaporation deposition, sputter deposition, or other suitable deposition process.

Referring to FIGS. 2-6, cross-sectional views of intermediate layers having other additional layers and/or being different types are shown in accordance with other embodiments of the present disclosure.

FIG. 2 shows a laser device 100B. Different from the laser device 100A shown in FIG. 1, the stack of epitaxial layers 104 further includes a current confinement structure 118. The current confinement structure 118 may be disposed between the active region 108 and the second reflective structure 110 and/or between the active region 108 and the first reflective structure 106. The current confinement structure 118 includes current confinement region 118C and a current conductive region 118o surrounded by the current confinement region 118C. For example, when the first reflective structure 106 and the second reflective structure 110 both include multiple pairs of layers having aluminum, the aluminum content of one or more of the layers of the first reflective structure 106 and/or of the second reflective structure 110 may be greater than 97% (which is defined as a “current confinement structure”). The layer(s) has the aluminum content greater than the aluminum content of other layers of the active region 108, the first reflective structure 106, and/or the second reflective structure 110. Therefore, after performing subsequent oxidation process, portions of the layer(s) having aluminum amount greater than 97% may be oxidized to form the current confinement region 118C, while the portions not be oxidized form the current conductive region 1180. The current conductive region 118o corresponds to the first opening 112o and has a third width larger than the first width of the first opening 112o.

In an embodiment, the material of the current conductive region 118o may include AlₓGa₁₋ₓAs, wherein 0.7≤x<0.98. The material of the current confinement region 118C is oxide corresponding to the material of the current conductive region 118o, such as AlₓO_{y}. The width of the current confinement region 118C of the current confinement structure 118 may be adjusted by appropriately controlling the oxidation rate and the oxidation processing time, so that the width of the current conductive region 118o may be also adjusted. Compared to the embodiment of FIG. 1, the current can be further restricted through the current confinement structure 118, thereby reducing the threshold current and improving the performance and luminous power of the laser device 100.

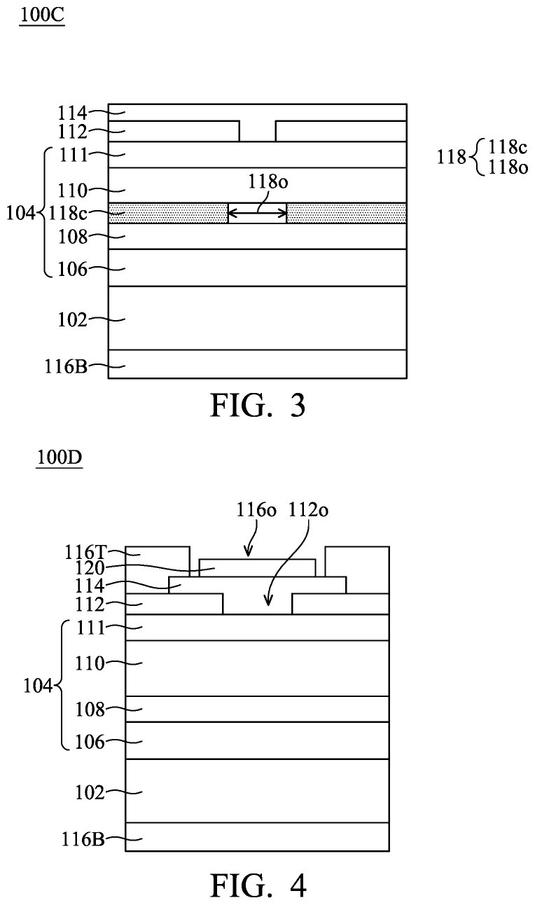

FIG. 3 shows a laser device 100C. Different from the laser device 100A as shown in FIG. 1, the intermediate layer 112 is a conductive material and the laser device 100C is devoid of the first electrode 116T on the first conductive layer 114 in the embodiment. In this embodiment, the intermediate layer 112 may include a metal. The metal may be germanium (Ge), beryllium (Be), gold (Au), platinum (Pt), aluminum (Al), nickel (Ni), or copper (Cu). Since the contact resistance between the intermediate layer 112 and the contact layer 111 is greater than the contact resistance between the first conductive layer 114 and the contact layer 111, when a current flow into the laser device 100C, most of the current flows into the central region 104A of the stack of epitaxial layers 104 through the first conductive layer 114. The intermediate layer 112 may act as the current-confining layer. In this embodiment, the first conductive layer 114 may also act as an electrode at the same time. Therefore, additional process to form the first electrode 116T may not be needed, thereby reducing the process cost. In other embodiments, according to the process and/or design requirements, the first electrode 116T (not shown) may also be formed on the first conductive layer 114 of the laser device 100C. In this embodiment, the laser device 100C may optionally include the current confinement structure 118 to increase the ability of current confinement. The current confinement structure 118 includes the current confinement region 118C and the current conductive region 118o as mentioned above.

FIG. 4 shows a laser device 100D. Different from the laser device 100A as shown in FIG. 1, the width of the first conductive layer 114 is smaller than that of the contact layer 111. The first conductive layer 114 does not cover all the intermediate layer 112, and the first electrode 116T covers the sidewalls of the first conductive layer 114 and directly contacts the intermediate layer 112. In this embodiment, the laser device 100 may further include an optical layer 120 disposed on the first conductive layer 114 to further increase the light emission quality of the laser device 100. In some embodiments, the optical layer 120 is a multi-layer structure and may include a light extraction layer, a transparent protective layer, a color conversion layer, a filter layer, or a combination thereof. The optical layer 120 may include an insulating material, such as SiO₂, SiNₓ, TiO₂, Ta₂O₅, Al₂O₃, or combinations of multi-layers thereof. In some embodiments, the optical layer 120 may be configured to correspond to the first opening 112o and have a width greater than the width of the first opening 112o. In this embodiment, the width of the optical layer 120 is smaller than the width of the second opening 116o. In other embodiments, the width of the optical layer 120 may be greater than or equal to the width of the second opening 116o.

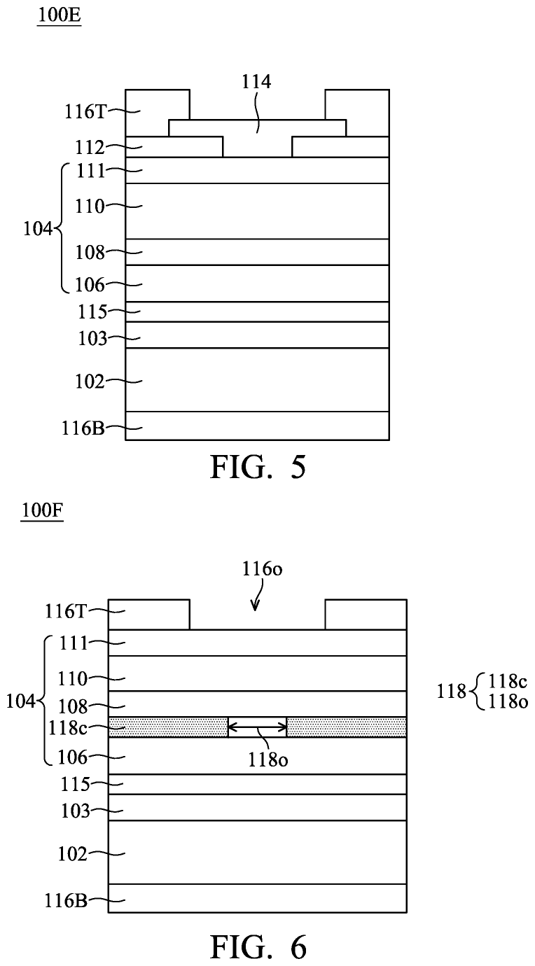

FIG. 5 shows a laser device 100E. Different from the laser device 100A shown in FIG. 1, the laser device 100E includes a bonding layer 103 disposed between the substrate 102 and the stack of epitaxial layers 104. The laser device 100E further includes the second conductive layer 115 disposed between the bonding layer 103 and the stack of epitaxial layers 104.

In some embodiments, the bonding layer 103 and the second conductive layer 115 may be assembled to act as an omni-directional reflector (ODR). The ODR is able to reflect the light emitted from the active region 108 and increase the external quantum efficiency (EQE). In some embodiments, the bonding layer 103 may facilitate the heat dissipation of the laser device 100. The bonding layer 103 may have a single layer or multi-layers structure and may include metal, such as Ag, Au, Ni, Cr, Pt, Pd, Rh, Cu, W, In, Pd, Zn, Ge, Bi, Al, or a combination thereof. The second conductive layer 115 may include a metal oxide material. The metal oxide material includes indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO), or indium zinc oxide (IZO).

FIG. 6 shows a laser device 100F. Different from the laser device 100E shown in FIG. 5, the laser device 100E does not include the first conductive layer 114 and the intermediate layer 112. The first electrode 116T is formed on and directly contacts the contact layer 111.

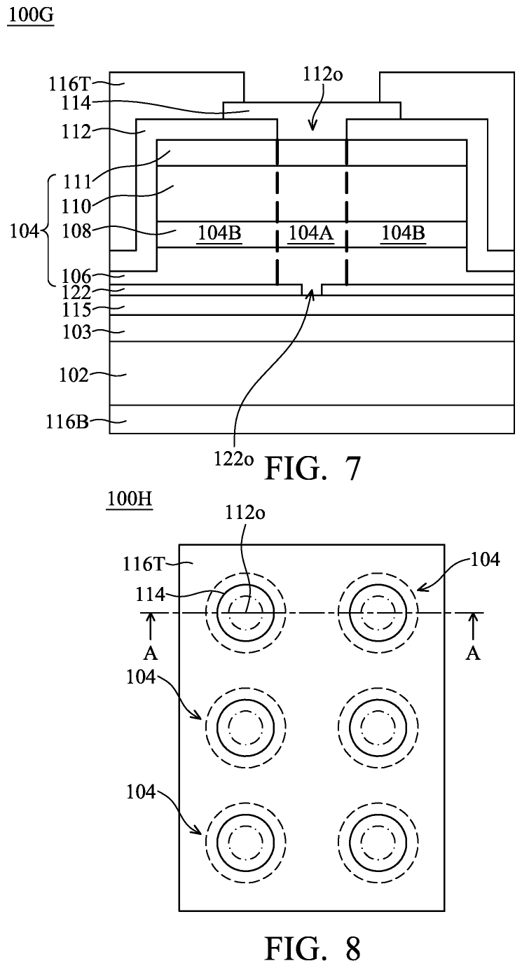

FIG. 7 shows a laser device 100G. Different from the laser device 100E shown in FIG. 5, the laser device 100E further includes the insulating layer 122 disposed between the stack of epitaxial layers 104 and the second conductive layer 115. The insulating layer 122 has a third opening 122o corresponding to the central region 104A of the stack of epitaxial layers 104. The third opening 122o may be located directly under the central region 104A of the stack of epitaxial layers 104. The insulating layer 122 may be a transparent material, such as SiO₂, SiNₓ, TiO₂, Ta₂O₅, Al₂O₃, or combinations of multi-layers thereof. The insulating layer 122 may be formed by chemical vapor deposition (CVD), plasma enhanced chemical vapor deposition (PECVD), atomic layer deposition (ALD), or other suitable deposition processes. As shown in FIG. 7, the third opening 122o is corresponding to the first opening 112o and has a width smaller than the width of the first opening 112o, so that the effect of current confinement can be increased and the performance and the luminous power of the laser device 100 can be improved. In addition, as shown in FIG. 7, the intermediate layer 112 covers the sidewalls of the active region 108, and the first electrode 116T covers the sidewalls of the intermediate layer 112.

FIG. 8 shows a top view of a laser device 100H. As shown in FIG. 8, the laser device 100H includes multiple stacks of epitaxial layers 104 periodically arranged on the substrate 102. In some embodiments, the multiple stacks of epitaxial layers 104 are arranged in an array form, for example, in a 3×2 array shown in FIG. 7, but the disclosure is not limited thereto. The arrangement or numbers of the stacks of epitaxial layers 104 as well as the distance between the stacks of epitaxial layers 104 may be adjusted by a person having ordinary skill in the art to meet the requirement. The laser device 100H further includes multiple first conductive layers 114 locating on the multiple stacks of epitaxial layers 104.

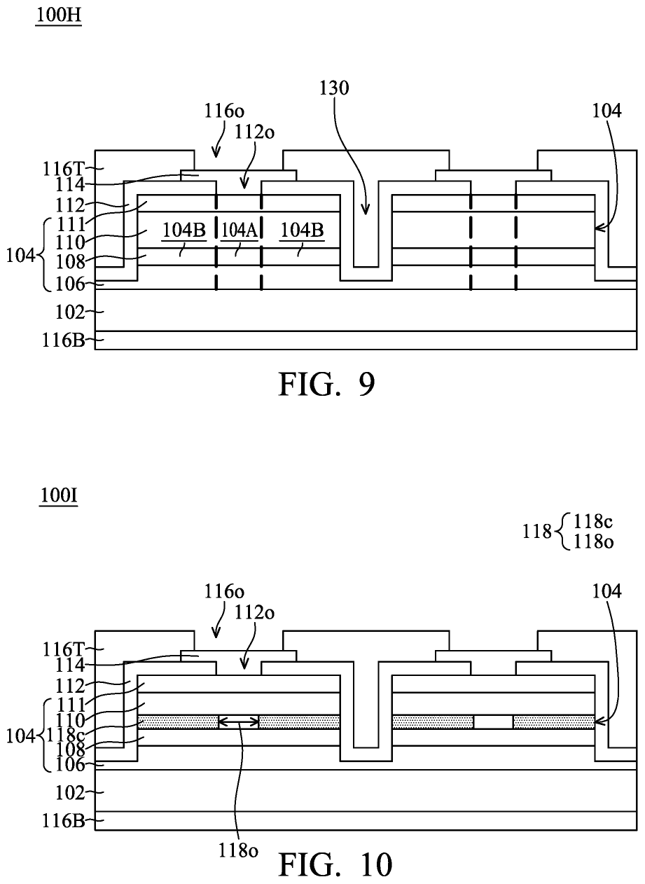

FIG. 9 shows a cross-sectional view taken along line A-A of FIG. 8. In this embodiment, a trench 130 is formed between the stack of epitaxial layers 104. The intermediate layer 112 fill in the trench 130 to cover the sidewalls of the active regions 108. The first electrode 116T is filled in the trench 130 and covers the intermediate layer 112. As shown in FIG. 9, the first reflective structures 106 of the stacks of epitaxial layers 104 are connected to each other, thereby increasing the process stability and enhancing the light emission efficiency of the laser device 100. In addition, the stacks of epitaxial layers 104 share the substrate 102, the first electrode 116T and the second electrode 116B, that is, the stacks of epitaxial layers 104 connect to the substrate 102 and electrically connect to the first electrode 116T and the second electrode 116B. Therefore, the process cost can be reduced, the stability of the laser device can be increased, and the product yield can be improved. The multiple stacks of epitaxial layers 104 may emit light simultaneously when operating the laser device 100.

FIGS. 10-14 show cross-sectional views of laser devices 100I-100M having other additional layers and/or different types of multiple laser units, in accordance with other embodiments of the present disclosure.

As shown in FIG. 10, different from the laser device 100H of FIG. 9, the stack of epitaxial layers 104 further include the current confinement structures 118. The structure of the laser device 100I may refer to the description of the laser device 100B shown in FIG. 2.

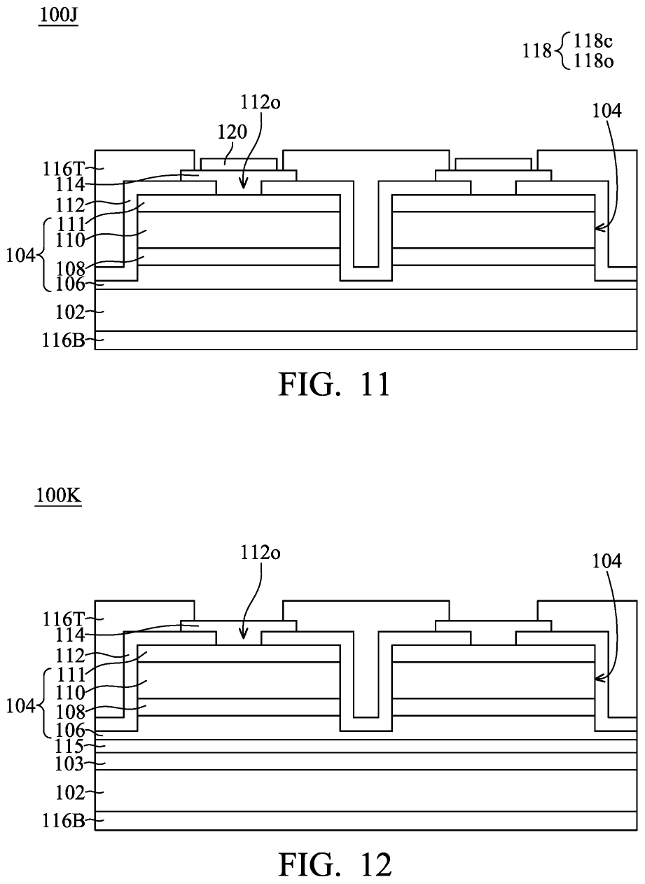

As shown in FIG. 11, different from the laser device 100H of FIG. 9, the laser device 100J further includes multiple optical layers 120, and each of the optical layers 120 locates on the first conductive layer 114. The structure of each of the laser device 100J may refer to the description of the laser device 100D shown in FIG. 4.

As shown in FIG. 12, different from the laser device 100H of FIG. 9, multiple stacks of epitaxial layers 104 connect to the second conductive layer 115 and the bonding layer 103. The structure of the laser device 100K may refer to the description of the laser unit 100E shown in FIG. 5.

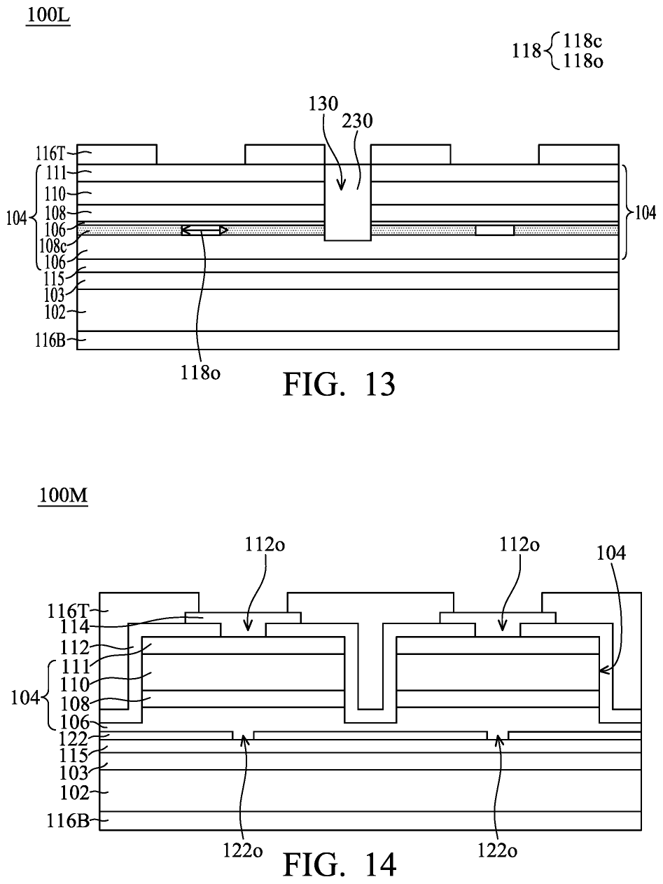

As shown in FIG. 13, different from the laser device 100K of FIG. 12, the laser device 100F does not include the first conductive layer 114 and the intermediate layer 112. The laser device 100K includes multiple first electrodes 116T formed on and directly contacting the contact layers 111. In this embodiment, the laser device 100K further includes an isolation structure 230 filling in the trench 130, and the first electrodes 116T are devoid of filling in the trench 130. The isolation structure 230 may include an insulating material, such as oxide insulating material, non-oxide insulating material, or a combination thereof. For example, the oxide insulating material may include silicon oxide (SiOₓ); the non-oxide insulating material may include silicon nitride (SiNₓ), benzocyclobutene (BCB), cycloolefin copolymer (COC), fluorocarbon polymer, calcium fluoride (CaF₂), or magnesium fluoride (MgF₂). In some embodiments, the isolation structure 230 may be formed by a deposition process, such as chemical vapor deposition (CVD), spin coating deposition, atomic layer deposition (ALD), or a combination thereof.

Still referring to FIG. 13, in some embodiments, the first electrodes 116T may be separated from each other Therefore, the different stack of epitaxial layers 104 can be independently controlled to emit light. In some embodiments, the first electrodes 116T of the stacks of epitaxial layers 104 may be connected to each other (not shown), thereby the multiple stacks of epitaxial layers 104 can be simultaneously controlled to emit light. The structure of the laser device 100L may refer to the description of the laser device 100F shown in FIG. 6.

As shown in FIG. 14, different from the laser device 100H of FIG. 9, the laser device 100M include an insulating layer 122 disposed between the stacks of epitaxial layers 104 and the second conductive layer 115. The insulating layer 122 has multiple third opening 122o corresponding to the multiple stacks of epitaxial layers 104. The insulating layers 122 covers the multiple stacks of epitaxial layers 104. The structure of the laser device 100M may refer to the description of the laser device 100G shown in FIG. 7.

The material of the substrate 102 may include a conductive material, such as gallium arsenide (GaAs), indium phosphide (InP), silicon carbide (SiC), gallium phosphide (GaP), gallium arsenide phosphide (GaAsP), zinc oxide (ZnO), zinc selenide (ZnSe), gallium nitride (GaN), lithium gallate (LiGaO₂), lithium aluminate (LiAlO₂), germanium (Ge), or silicon (Si). In some embodiments, when the substrate 102 is provided for growing the stack of epitaxial layers 104, a single crystal material that lattice matches or closely lattice match to the stack of epitaxial layers 104 may be selected as the material of the substrate 102.

Accordingly, the structures of laser devices having an intermediate layer and a conductive layer are generally described by the present disclosure, wherein the conductive layers may be disposed above and/or below the current confinement layer of the laser device. For example, a conductive layer may be formed above and/or below the opening of the current confinement layer according to the design requirements of the vertical cavity surface emitting laser (VCSEL), and the current confinement layer can locate above and/or below the active region.

According to the design requirements of the laser device, the current concentrated at the edge of the opening of the current confinement layer may be reduce by deposing the intermediate layer and/or the conductive layer, thereby improving the quality of the laser device. For example, the conductive layer may be formed above the opening of the intermediate layer in the embodiment that the intermediate layer act as a current-confining layer. The current confinement structure may be formed in the stack of epitaxial layers to increase the function of current confinement in some embodiments. Besides, in the embodiment with the current confinement structure, the intermediate layer may include metal to further reduce the current concentrating at the opening edge of the current confinement structure. In some embodiments, the conductive layer may be formed below the current confinement structure to reduce the current concentrating at the opening edge of the current confinement structure. Besides, in some embodiments, the bonding layer to connect the substrate and the conductive layer. In some embodiments, the insulating layer having an opening may be formed on the conductive layer to further increase the current-confining-function. In addition, in some embodiments, the conductive layers may be formed above and below the current confinement structure respectively, in order to further reduce the current concentrating at the opening edge of the current confinement structure.

It should be appreciated that the scope of the present disclosure is not limited to the technical solution of specific combination of the abovementioned technical features shown in the drawings, but also covers other technical solutions of any combinations of the abovementioned technical features or the equivalents. The embodiments described above may be arbitrarily combined to form new embodiments, and all the new embodiments formed by the combinations are within the protection scope of the present disclosure.

Although some embodiments of the present disclosure and advantages thereof have been described, it should be appreciated that those skilled in the art can make changes, substitutions and modifications without departing from the spirit and scope of the present application. For example, those skilled in the art may readily understand that many of the components, functions, processes, and materials described herein may be changed without departing from the scope of the present disclosure. In addition, the protection scope of the present disclosure is not limited to the process, machine, manufacture, material composition, method and steps in the specific embodiments described herein. It should be readily appreciated by those skilled in the art that the current or future developed processes, machines, manufactures, material compositions, devices, methods and steps can be used in accordance with the present application as long as they can perform substantially the same functions or obtain substantially the same results in the embodiments described herein. Therefore, the protection scope of the present application includes the abovementioned process, machine, manufacture, material compositions, device, method and steps.

What is claimed is:

1. A laser device, comprising:
a stack of epitaxial layers having a central region and an edge region and comprising:
a first reflective structure;
an active region disposed on the first reflective structure; and
a second reflective structure disposed on the active region;
a first conductive layer disposed on the stack of epitaxial layers, wherein the first conductive layer covers the central region and a part of the edge region of the stack of epitaxial layers;
an intermediate layer having a first opening corresponds to the central region of the stack of epitaxial layers, wherein the intermediate layer comprises insulating material or metal; and
a first electrode disposed on the first conductive layer.

2. The laser device as claimed in claim 1, wherein the first electrode has a second opening corresponding to the first opening.

3. The laser device as claimed in claim 2, wherein the first opening has a first width and the second opening has a second width different from the first width.

4. The laser device as claimed in claim 3, wherein the second width of the second opening is greater than the first width of the first opening.

5. The laser device as claimed in claim 2, wherein the laser device comprises a plurality of the stack of epitaxial layers electrically connect to the first electrode.

6. The laser device as claimed in claim 1, wherein the stack of epitaxial layers further comprises a current confinement structure between the active region and the second reflective structure.

7. The laser device as claimed in claim 6, wherein the current confinement structure comprises a current conductive region corresponding to the first opening and has a third width larger than the first width of the first opening.

8. The laser device as claimed in claim 1, further comprising:
a substrate disposed under the stack of epitaxial layers; and
a second conductive layer disposed between the substrate and the stack of epitaxial layers.

9. The laser device as claimed in claim 8, further comprising
a bonding layer disposed between the substrate and the second conductive layer.

10. The laser device as claimed in claim 8, further comprises an insulating layer disposed between the second conductive layer and the stack of epitaxial layers, wherein the insulating layer has a third opening located directly under the central region of the stack of epitaxial layers.

11. The laser device as claimed in claim 1, wherein the laser device further comprises a plurality of the stack of epitaxial layers.

12. The laser device as claimed in claim 11, further comprising a second electrode, and the plurality of the stack of epitaxial layers electrically connect to the second electrode.

13. The laser device as claimed in claim 1, wherein the active region has sidewalls and the intermediate layer encapsulates the sidewalls of the active region.

14. The laser device as claimed in claim 1, further comprising an optical layer disposed on the first conductive layer and located corresponding to the first opening.

15. The laser device as claimed in claim 14, wherein the optical layer is a multi-layer structure.

16. A laser device, comprising:
a substrate;
a stack of epitaxial layers disposed on the substrate and comprising:
a first reflective structure;
a current confinement structure disposed on or within the first reflective structure, wherein the current confinement structure comprises a current conductive region;
an active region disposed on the current confinement structure; and
a second reflective structure disposed on the active region;
a conductive layer disposed between the substrate and the stack of epitaxial layers;
a bonding layer disposed between the substrate and the conductive layer; and
a first electrode disposed on the stack of epitaxial layers.

17. The laser device as claimed in claim 16, wherein the first electrode comprises an opening corresponding to the current conductive region.

18. The laser device as claimed in claim 17, wherein the opening has a fourth width and the current conductive region has a fifth width different from the fourth width.

19. The laser device as claimed in claim 18, wherein the fourth width of the opening is larger than the fifth width of the current conductive region.

20. The laser device as claimed in claim 17, wherein the laser device comprises a plurality of the stack of epitaxial layers electrically connect to the first electrode.
